(19) United States
(12) Patent Application Publication
(10) Pub. No.: US 2010/0103517 A1
(43) Pub. Date: Apr. 29, 2010

(54) SEGMENTED FILM DEPOSITION

(76) Inventors: Mark Alan Davis, Springville, UT (US); Benjamin Spencer Center, Spanish Fork, UT (US)

Correspondence Address: THORPE NORTH & WESTERN, LLP., P.O. Box 1219, SANDY, UT, 84091-1219, US

(21) Appl. No.: 12/507,570

(22) Filed: Jul. 22, 2009

Related U.S. Application Data
(60) Provisional application No. 61/109,250, filed on Oct. 29, 2008.

(51) Int. Cl. G02B 27/28; B32B 5/00; B05D 5/06; C23C 14/34

(52) U.S. Cl. 359/486; 428/143; 428/195.1; 427/163.1; 204/192.26

(57) ABSTRACT

A segmented film deposition wire grid polarizer with a separate coating on top of each rib.

### CLAIM OF PRIORITY

Priority of U.S. Provisional Patent Application Ser. No. 61/109,250 filed on Oct. 29, 2008, is claimed, and is herein incorporated by reference.

### FIELD OF THE INVENTION

The present invention relates to wire grid polarizers.

### BACKGROUND

As shown in FIG. 1, a wire grid polarizer can comprise an array of ribs 12 on a substrate 11. The ribs have a pitch P, designed to allow polarization of the desired electromagnetic wavelength. Additional rib layers 13 and 14 may be desirable for improved polarizer performance. For example, the additional layers 13 and 14 can result in improved transmission of the desired polarization or can absorb the unwanted polarization. Layer 13 and layer 14 can represent a single layer each or can represent multiple layers.

The structure of FIG. 1 is typically made by applying layer 12 as a continuous film, applying the desired additional layers 13 and 14, then patterning and etching through all films at one time to create the rib structure. The requirement of etching through layers 12, 13, and 14 can create manufacturing difficulties and/or polarizer structural limitations. For example, the aspect ratio, as defined by rib height H divided by rib width W, can have an upper limit due to the difficulty of etching structures with high aspect ratios. Some materials, which may be desirable to use as layers 13 or 14, can be very difficult, or perhaps even impossible, to etch. Etching through a structure with multiple different layered materials can be complex, and can require multiple etching steps and/or multiple etching tools. Note that the rib width W is substantially the same for all layers 12, 13, and 14.

In order to simplify the etching process, and to allow more materials to be used as additional rib layers 13 and 14, it may be advantageous to pattern and etch through layer 12, then sputter the added layers 13 and 14 on top of the ribs 12. Two results of deposition coating on top of polarizer ribs are conformal coating and directional coatings.

A conformal coating is shown in FIG. 2. An additional layer 21 can be sputtered on top of the ribs 22, but the additional layer 21 can also coat the area 23 between the ribs. Layer 21 coats and conforms to the surface of the ribs 12. For some applications, this conformal coating may be beneficial. For other applications, coating between the ribs 23 may be detrimental. For example, a conformal coating can be detrimental to polarizer performance.

Directional coatings are shown in FIG. 3 and FIG. 4. As shown in FIG. 3, the coating 31 does not conform to the entire surface of the ribs, but does apply a portion of the coating to the substrate between the ribs 23. This portion between the ribs 23 is undesirable for some polarizer applications.

FIG. 4 shows coating as applied by shadow-coating sputtering. The coating is applied at an angle. Results are limited by the aspect ratio of the structure and angle of deposition. With this process, the substrate area between the ribs 23 is not coated. Disadvantages of shadow coating include difficult process control and a coating 41 which is primarily on one side of the rib 44 but not the other side 45.

### SUMMARY OF THE INVENTION

It has been recognized that it would be advantageous to add additional coatings on top of wire grid polarizer ribs without etching. It has been recognized that it would be advantageous to apply such coatings to only the ribs and not to the substrate between the ribs. It has been recognized that it would be advantageous to apply such coatings in a uniform manner across the top of the ribs.

The present invention is directed to a segmented film deposition device including a substrate with a generally parallel arrangement of thin, elongated elements disposed over the substrate. The elements have a surface opposite of the substrate and sides extending down to the substrate. A coating is on the surface of the elements and continues partially down both sides of the elements without coating the substrate exposed between the elements.

The present invention also presents a wire-grid polarizer device with a substrate and a generally parallel arrangement of thin, elongated, conductive wires disposed over the substrate. The wires have a surface opposite of the substrate and sides extending down to the substrate. A segmented coating is on the surface of the wire with each segment continuing partially down both sides of a wire without coating the substrate exposed between the wires. Each segment is aligned over and wider than the wire.

The present invention also presents a method for fabricating a wire-grid polarizer, comprising: forming an array of parallel spaced-apart wires on a substrate; and depositing a segmented film on the wires with the segments aligned with the wires and continuing partially down both sides of the wires without coating the substrate exposed between the wires.

### BRIEF DESCRIPTION OF THE DRAWINGS

Additional features and advantages of the invention will be apparent from the detailed description which follows, taken in conjunction with the accompanying drawings, which together illustrate, by way of example, features of the invention; and, wherein:

FIG. 1 is a schematic cross-sectional side view of a prior art device with coated ribs;

FIG. 2 is a schematic cross-sectional side view of a prior art device with conformal coated ribs;

FIG. 3 is a schematic cross-sectional side view of a prior art device with directionally coated ribs;

FIG. 4 is a schematic cross-sectional side view of a prior art device with directionally coated ribs;

FIG. 5 is a schematic cross-sectional side view of a segmented film deposition device in accordance with an embodiment of the present invention;

FIG. 6 is a schematic cross-sectional side view of a segmented film deposition device in accordance with an embodiment of the present invention;

FIG. 7 is a schematic cross-sectional side view of a segmented film deposition device in accordance with an embodiment of the present invention;

FIG. 8 is a schematic cross-sectional side view of a segmented film deposition device in accordance with an embodiment of the present invention;

FIG. 9 is a schematic cross-sectional side view of a prior art rib structure;

FIG. 10 is a schematic cross-sectional side view of a segmented film deposition device in accordance with an embodiment of the present invention;

FIG. 11 is a schematic cross-sectional side view of a segmented film deposition device in accordance with an embodiment of the present invention;

FIG. 12 is a schematic cross-sectional side view of a segmented film deposition device in accordance with an embodiment of the present invention;

FIG. 13 is a schematic cross-sectional side view of a segmented film deposition device in accordance with an embodiment of the present invention;

FIG. 14 is a scanning electron microscope view of a segmented film deposition device in accordance with an embodiment of the present invention;

FIG. 15 is a scanning electron microscope view of a segmented film deposition device in accordance with an embodiment of the present invention;

FIG. 16 is a scanning electron microscope view of a segmented film deposition device in accordance with an embodiment of the present invention; and

FIG. 17 is a scanning electron microscope view of a segmented film deposition device in accordance with an embodiment of the present invention.

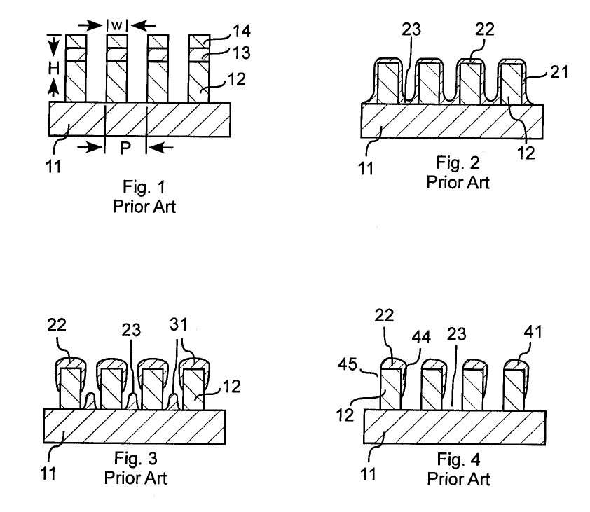

### DETAILED DESCRIPTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

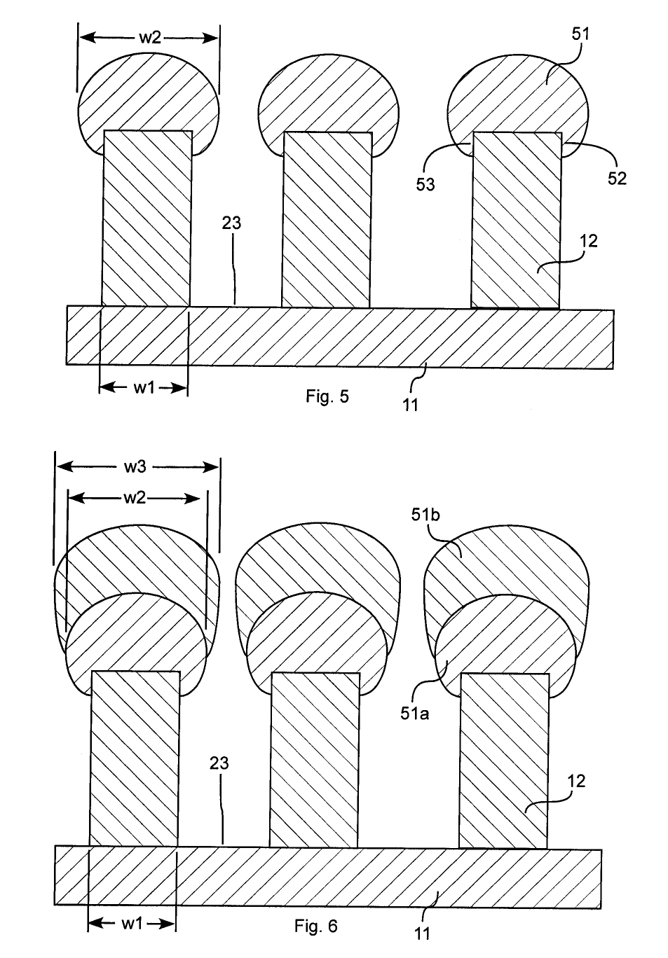

As shown in FIG. 5, segmented film deposition (SFD) allows sputtering of a segmented coating 51 on top of ribs, elements or wires 12, but not on the substrate between the ribs 23. Both sides of the ribs 52 and 53 can have a small amount of coating continuing partially down both sides. Polarization performance can be improved by not coating the substrate between the ribs 23. The segmented coating 51 can form segments or elongated beads aligned on top of the ribs, elements or wires. In addition, the segments or beads can have a symmetrical cross-sectional shape. Furthermore, the segments or beads can be wider than the ribs, elements or wires. The width of the elements w1, where the coating begins, can be less than the maximum width of the coating w2. The segments or beads can have a bulbous cross-sectional shape with a rounded top surface and that is narrower at a lower end with respect to a higher portion. Because the coatings in the SFD process are not required to be etched, a broader selection of coatings is available, including coatings which would be difficult, or impossible, to etch. SFD can be used on polarizer structures such as those shown in U.S. Pat. Nos. 6,785,050; 6,208,463; 6,108,131; 6,710,921; 6,452,724; 6,122,103; and 6,243,199 which are herein incorporated by reference.

The substrate 11 can be any material including metal, dielectric, or polymer, depending on the desired application. The ribs 12 can be the same material as the substrate 11 or can be a different material. The ribs 12 can be the same material as the coating 51 or can be a different material. The ribs and coating can be any material including metal, dielectric, or polymer. The ribs can be a single material, or can be layers of different materials. The coating can be a single material or it can be layers of different materials.

For example, a wire grid polarizer coated by SFD can have a substrate which is transparent to the desired electromagnetic radiation. The ribs can be a conductive material, such as aluminum. Wire grid polarizers are often used for polarization of ultraviolet, visible, or infrared light. The pitch can be less than half of the wavelength of the light to be polarized. The SFD material can be selected to optimize polarizer performance or structural characteristics.

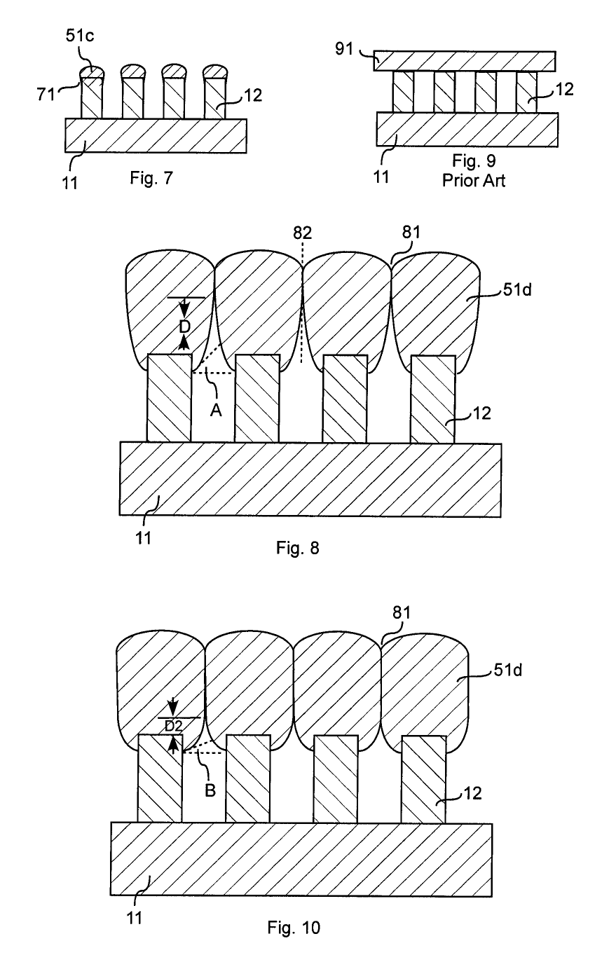

The coating can be applied in a single layer or in multiple layers 51a and 51b as shown in FIG. 6. The maximum width w3 of the top layer 51b can be wider than the maximum width w2 of a lower layer 51a. Layers 51a and 51b can both be the same material or can be different materials. Layers 51a and 51b can each represent a single layer or can represent multiple layers such that there can be many more than two layers applied. As shown in FIG. 5, the coating can extend down the side of the rib 52 or 53, or as shown in FIG. 7, much of this coating 51c on the side of the rib 71 can be removed by etching.

As shown in FIG. 8, the coating 51d can be increased in depth until the coatings 51d on separate ribs touch 81 without attaching one another to form a continuous layer. Although the coatings on top of different ribs touch 81, the coating on each rib has a boundary or slip plane 82. This is distinct from the layer 91 shown in FIG. 9, in which there is no such separation in the coating for individual ribs. Having a slip plane 82 between the coating of different ribs can result in increased device durability or flexibility as the coatings on separate ribs can thus slide past each other as the device is flexed.

The sputtering process can be controlled to determine the coating depth D at which the ribs touch. Note that angle A in FIG. 8 is larger than angle B in FIG. 10. With a smaller angle B, the coating will touch at a lower depth D2. This may be advantageous if it is desired to have a thinner overall coating thickness. In other applications, it may be desirable to have a thicker coating, but only have a smaller point of contact, or smaller slip plane, to allow less friction at the slip plane, such as is shown in FIG. 8. A slower rate of coating 51d deposition results in the structure of FIG. 8, with a larger angle A. A faster rate of coating 51d deposition results in the structure of FIG. 10, with a smaller angle B.

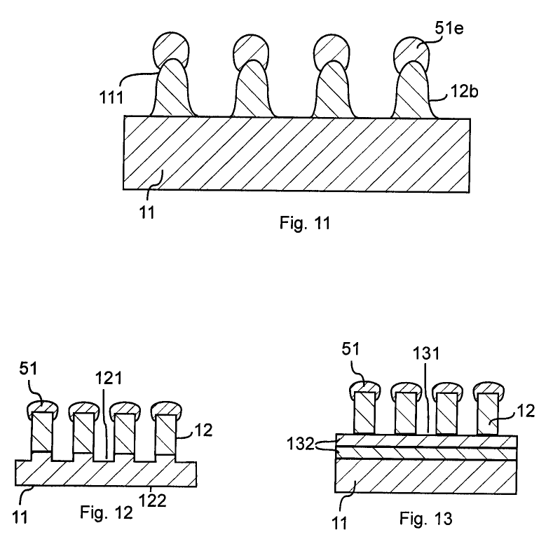

Although the ribs in FIGS. 5, 6, 7, 8, and 10, show rectangular shaped ribs 12, the SFD process works with other shaped ribs. For example, see coating 51e on ribs 12b with rounded tops 111 in FIG. 11.

The SFD process can be used with many different rib and substrate structures, such as the structure of FIG. 12 in which the substrate between the ribs 121 is etched to form substrate ribs 122 beneath the ribs 12. Alternatively, as shown in FIG. 13, there may be additional blanket film layers 132 between the substrate and the ribs. The area between the ribs 131 may be etched to form additional ribs in the film layers.

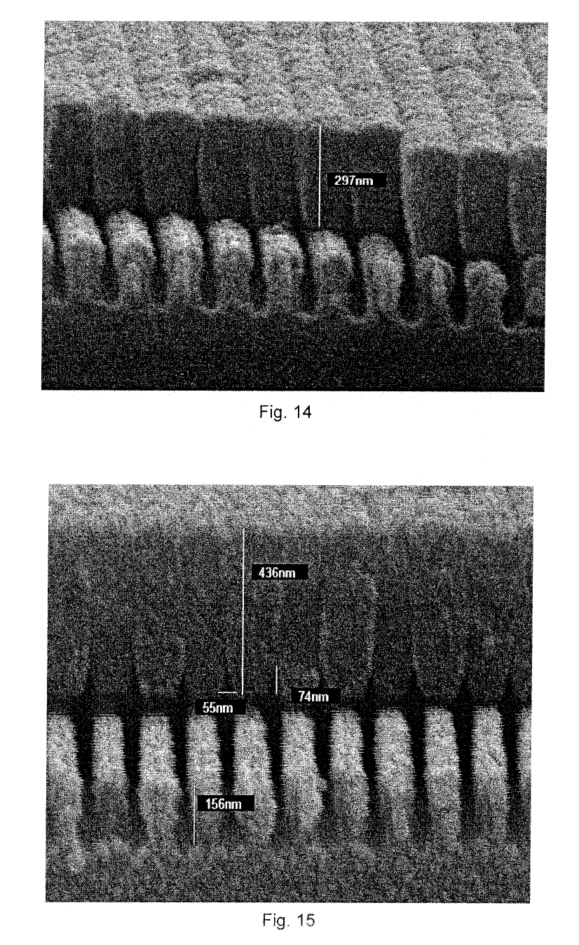

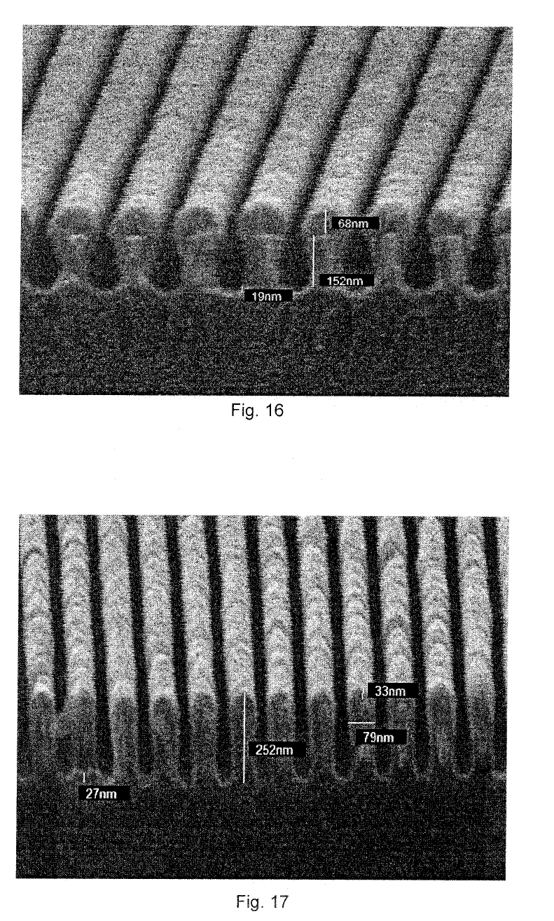

Successful SFD has been performed on a NEXX Nimbus 5000 sputter coater to apply a coating of silicon dioxide and silicon nitride, with power of 5000 watts, chamber pressure of 4 mtorr, argon flow of 28 sccm, oxygen flow of 43 sccm, scan length of 325 mm, scan speed of 42.2 mm/sec. SFD was applied on wire grid polarizers on 200 mm wafers with wire grid pitch of about 120 nm, rib height of 20-220 nm, and rib width of 40-60 nm. SEM photographs of SFD coatings are shown in FIGS. 14-17.

SFD may be optimized by adjusting the process parameters of chamber pressure, power settings, sputter gas flow rate, dilution gas flow rate, type of reactive gas used, bottom chuck bias, chuck temperature, alignment of target to wafer, wafer size, rib aspect ratio, and rib pitch.

Process parameters that result in a slower rate of growth of the coated material, such as a lower chamber pressure or lower power, result in a more vertical profile of the coated material 51d, or larger angle A, as shown in FIG. 8. Process parameters that result in a faster rate of growth of the coated material, such as a higher chamber pressure or higher power, result in a less vertical profile of the coated material 51d, or smaller angle B, as shown in FIG. 10.

It is to be understood that the above-referenced arrangements are only illustrative of the application for the principles of the present invention. Numerous modifications and alternative arrangements can be devised without departing from the spirit and scope of the present invention. While the present invention has been shown in the drawings and fully described above with particularity and detail in connection with what is presently deemed to be the most practical and preferred embodiment(s) of the invention, it will be apparent to those of ordinary skill in the art that numerous modifications can be made without departing from the principles and concepts of the invention as set forth herein.

What is claimed is:

1. A segmented film deposition device, comprising:
a) a substrate;
b) a generally parallel arrangement of thin, elongated elements disposed over the substrate, the elements having a surface opposite of the substrate and sides extending down to the substrate;
c) a coating on the surface of the elements and continuing partially down both sides of the elements without coating the substrate exposed between the elements.

2. A device in accordance with claim 1, wherein the coating is segmented and the segments are aligned with the elements; and wherein the segments are wider than the element.

3. A device in accordance with claim 1, wherein the coating forms an array of elongated beads aligned on top of the arrangement of elements.

4. A device in accordance with claim 3, wherein the beads are wider than the elements.

5. A device in accordance with claim 3, wherein the beads have a bulbous cross-sectional shape.

6. A device in accordance with claim 3, wherein adjacent beads touch one another without attaching to one another to form a continuous layer, and defining a slip plane therebetween.

7. A device in accordance with claim 3, wherein the beads have a rounded top surface.

8. A device in accordance with claim 1, wherein the beads have a narrower lower end with respect to a higher portion.

9. A device in accordance with claim 1, wherein the coating includes at least two layers.

10. A device in accordance with claim 1, wherein the generally parallel arrangement of thin, elongated elements includes a conductive material forming wires spaced apart with a pitch less than a wavelength of incident light defining a wire-grid polarizer.

11. A wire-grid polarizer device, comprising:
a) a substrate;
b) a generally parallel arrangement of thin, elongated, conductive wires disposed over the substrate, the wires having a surface opposite of the substrate and sides extending down to the substrate;
c) a segmented coating on the surface of the wire with each segment continuing partially down both sides of a wire without coating the substrate exposed between the wires, and each segment being aligned over and wider than the wire.

12. A device in accordance with claim 11, wherein adjacent segments touch one another without attaching to one another to form a continuous layer, and defining a slip plane therebetween.

13. A device in accordance with claim 11, wherein the segments have a narrower lower end with respect to a higher portion.

14. A method for fabricating a wire-grid polarizer, comprising;
a) forming an array of parallel spaced-apart wires on a substrate; and
b) depositing a segmented film on the wires with the segments aligned with the wires and continuing partially down both sides of the wires without coating the substrate exposed between the wires.

15. A method in accordance with claim 14, wherein depositing further includes sputtering the segmented film without coating the substrate between the wires.

16. A method in accordance with claim 14, wherein depositing further includes depositing the segmented film so that the segments are wider than the wires.

17. A method in accordance with claim 14, wherein depositing further includes depositing the segmented film so that the segments have a bulbous cross-sectional shape.

18. A method in accordance with claim 14, wherein depositing further includes depositing the segmented film until the segments touch one another without attaching to one another to form a continuous layer, and defining a slip plane therebetween.

19. A method in accordance with claim 14, wherein depositing includes depositing a segmented film so that the segments a rounded top surface.

20. A method in accordance with claim 14, wherein depositing further includes depositing the segmented film so that the segments have a narrower lower end with respect to a higher portion.

21. A method in accordance with claim 14, wherein depositing further includes depositing at least two layers.
